(19) United States
(12) Patent Application Publication
(10) Pub. No.: US 2014/0007935 A1
(43) Pub. Date: Jan. 9, 2014

(54) HYBRID DIELECTRIC-METALLIC BACK REFLECTOR FOR PHOTOVOLTAIC APPLICATIONS

(71) Applicants: James Mutitu, Newark, DE (US); Shouyuan Shi, Newark, DE (US); Dennis Prather, Newark, DE (US); Allen Barnett, Landenberg, PA (US)

(72) Inventors: James Mutitu, Newark, DE (US); Shouyuan Shi, Newark, DE (US); Dennis Prather, Newark, DE (US); Allen Barnett, Landenberg, PA (US)

(73) Assignee: University of Delaware, Newark, DE (US)

(21) Appl. No.: 13/885,903

(22) PCT Filed: Nov. 18, 2011
(86) PCT No.: PCT/US2011/061403

§ 371 Date: Sep. 10, 2013

Related U.S. Application Data
(60) Provisional application No. 61/415,513, filed on Nov. 19, 2010.

(51) Int. Cl. H01L 31/0232

(52) U.S. Cl. CPC H01L 31/02327
USPC 136/256

(57) ABSTRACT

A photovoltaic device includes a photovoltaic layer configured to convert light into electrical power, a distributed Bragg reflector (DBR) layer having one to three periods disposed adjacent the photovoltaic layer, a metal layer, disposed adjacent the DBR layer, configured to reflect light passed through the photovoltaic layer to the DBR layer, and a phase matching layer disposed between the metal layer and the DBR layer, the phase matching layer configured to match a phase between the DBR layer and the metal layer over a selected wavelength band. The metal layer has a non-uniformed textured surface facing the phase matching layer. The photovoltaic device further includes an anti-reflection coating layer disposed on a top surface of the photovoltaic layer, and a substrate on which the metal layer is disposed. The substrate may be textured on a surface facing the metal layer.

### PRIORITY CLAIM

This application claims priority to U.S. Provisional Patent Application Ser. No. 61/415,513, filed Nov. 19, 2010, the disclosure of which is incorporated herein by reference.

### STATEMENT REGARDING FEDERALLY SPONSORED RESEARCH

The present invention was supported in part by Grant Number HR0011-0709-0005 from the Defense Advanced Research Projects Agency. The United States Government may have certain rights to the present invention.

### FIELD OF THE INVENTION

The present invention relates in general to photovoltaic devices, such as solar cells, with back surface mirrors of reduced complexity and good reflectance characteristics.

### BACKGROUND OF THE INVENTION

Back surface mirrors, or back reflectors also referred to as “BSRs”, are of great value and importance in thin film solar cells. Efficient back reflectors improve the light trapping capacity. The science of back surface reflectance is dictated by a number of important aspects, in addition to the reflective properties. These aspects include the back contact technology, material conductivity, passivation and the material adherence properties. The combination of these features gives rise to a complex interplay, between the optical and electrical functionality.

High reflectance back surface reflectors (BSRs) generally comprise a stack of multilayer dielectrics, each with a high refractive index contrast between two layers of alternating high and low refractive index. Each such pair of layers is referred to as a period. Among different types of BSRs are Distributed Bragg Reflectors (DBRs), dichroic mirrors, one dimensional photonic crystals, cold mirrors and any other type of dielectric mirror. In the case of conventional dielectric multilayer structures, the structures typically include many periods (usually six or more) to realize high reflectance. The terms Distributed Bragg Reflectors or DBRs will be used herein to include all such paired layer dielectric reflectors useful as BSRs.

Metals alone have also been used as back surface reflectors. Metals used for this purpose are generally those that exhibit high reflectance characteristics, typically silver or gold. These may be expensive in terms of material cost; more importantly, they have not been known to allow for fewer DBR layers. Aluminum is also often used as a back surface reflector and contact material; however, even though it is cheaper than silver or gold, it is not known to have very high reflectance qualities.

### SUMMARY OF THE INVENTION

Embodiments of the present invention include a photovoltaic device with a hybrid dielectric-metallic back surface reflector comprised of a multilayer DBR stack including 1 to 3 DBR periods, overlying a phase matching layer and a metallic layer.

In general, photovoltaic devices of this invention include a photovoltaic layer configured to convert light into electrical power, a DBR layer having no more than three periods disposed adjacent the photovoltaic layer, a metal layer, disposed adjacent the DBR layer and configured to reflect light passed through the photovoltaic layer and the DBR layer and a phase matching layer disposed between the metal layer and the DBR layer, the phase matching layer configured to match phase over a selected wavelength band of incident light.

The photovoltaic device may further include an anti-reflection coating layer (ARC) disposed on the front surface of the photovoltaic layer, and a substrate on which the metal layer is disposed.

According to one aspect of the invention, the photovoltaic device includes a glass substrate.

According to another aspect, the photovoltaic device includes a crystal silicon substrate that may be textured.

Preferably, the photovoltaic device comprises an amorphous silicon photovoltaic layer, on the order of 500 nanometers thick, with a back surface reflector comprised of a single period DBR overlying a silicon dioxide phase matching layer and a metal layer with a texturized surface. The preferred metal is aluminum but other metals, such as nickel, chromium, palladium, silver, copper, gold and molybdenum may also be used.

### BRIEF DESCRIPTION OF THE DRAWINGS

Exemplary embodiments will be explained in greater detail below with reference to the figures, in which:

FIG. 1 is a perspective schematic view of one embodiment of a photovoltaic device according to the present invention;

FIG. 2 is a perspective schematic view of an embodiment of the invention as shown in FIG. 1, further including a substrate and an ARC layer;

FIG. 3 is a schematic cross-sectional view of the embodiment shown in FIG. 2;

FIG. 4 is a scanning electron microscope (SEM) image of the surface of an actual photovoltaic device like that shown schematically in FIGS. 2 and 3;

FIG. 5 is a perspective schematic of another embodiment of the photovoltaic device like that shown in FIG. 2 but having a crystalline silicon substrate (c-Si);

FIG. 6 is a schematic cross-sectional diagram of the embodiment of the invention shown in FIG. 5;

FIG. 7(AA) is a graphic representation of a photovoltaic device having a regular upright pyramidal (Pymd Struct) textured surface conforming to a rough surface of a metal layer overlaying a similarly textured c-Si substrate;

FIG. 7(AB) is an SEM image of an actual photovoltaic device like that shown graphically in FIG. 7(AA), wherein the substrate is crystalline silicon and with some layers broken away;

FIG. 7(BA) is a graphic representation of a photovoltaic device, having an etched diffraction grating (Grating Samp) textured surface conforming to similarly configured undersurfaces of a metal layer and an underlying substrate;

FIG. 7(BB) is an SEM image of an actual photovoltaic device like that shown graphically in FIG. 7(BA), wherein the substrate is crystalline silicon and with some layers broken away;

FIG. 7(CA) is a graphic representation of a photovoltaic device having a random pyramidal-like textured surface (Random Pymd) conforming to similarly textured undersurfaces of a metal layer and an underlying substrate;

FIG. 7(CB) is an SEM image of an actual photovoltaic device like that shown graphically in FIG. 7(CA), with a crystalline silicon substrate and with some layers broken away;

FIG. 8(A) graphically illustrates the calculated relationship between the light absorption characteristics of a photovoltaic device according to one embodiment of the present invention and the wavelength of that light for various thicknesses of the photovoltaic layer;

FIG. 8(B) graphically illustrates the calculated relationship between the light transmission characteristics of a photovoltaic device according to one embodiment of the present invention and the wavelength of that light for various thicknesses of the photovoltaic layer;

FIG. 9 is a graph of the calculated reflectance characteristics of photovoltaic devices like one exemplary embodiment of the present invention with a varying number of DBR periods, but lacking a metal layer;

FIG. 10 is a graph of the calculated reflectance characteristics of photovoltaic devices like those referenced for the data graphed in FIG. 9, but including a phase matching layer and a metal layer;

FIG. 11 is a graph of the calculated reflectance characteristics of photovoltaic devices with reflecting layers comprising aluminum only, a 1 layer DBR only, and a 1 layer DBR with an added aluminum layer;

FIG. 12 is a graph of reflectance versus change in thickness of the change of reflectance layer in a photovoltaic device having a 1 Layer DBR structure with an added phase matching layer and an aluminum underlayer;

FIG. 13 is a diagram showing the idealized propagation of a wave through a photovoltaic device including a back reflector assembly comprising a 1 layer DBR, an added phase matching layer and an aluminum layer as in the exemplary embodiments of the present invention;

FIG. 14 is a graph of the calculated absorption characteristics for a photovoltaic device, with an assumed smooth surface on the metal layer facing a phase matching layer according to one embodiment of the present invention, and as compared to similar structures but lacking elements of the present invention;

FIG. 15 is a graph of experimental data reflecting a comparison of the same structures referenced with respect to FIG. 14 but with an actual metal surface have some roughness;

FIG. 16 is a graph of the experimental and calculated (i.e. simulated) absorption characteristics for a photovoltaic device according to one embodiment of the present invention where the calculated results are based on a rough surface on the metal layer;

FIG. 17 is a graph of experimental data showing the enhancement factor of absorption of incident light in the wavelength range of 600-800 nm for photovoltaic devices comprised (1) of an anti-reflective outer layer and an amorphous silicon photovoltaic layer only, (2) a similar device with a one layer DBR reflectance back layer, (3) a similar device with a one layer DBR and an aluminum underlayer;

FIG. 18 is a plot of short circuit current characteristics (Jsc) of photovoltaic devices comparing one embodiment of the present invention to devices omitting one or more elements of the invention;

FIG. 19 is a plot of the calculated absorption characteristics at different angles of incident light for a photovoltaic device according to one embodiment of the present invention;

FIG. 20 is a schematic flow diagram showing the steps involved in the preparation of a photovoltaic device on a textured crystalline silicon substrate according to other embodiments of the present invention;

FIG. 21 is a schematic diagram illustrating the use of deep ultra violet lithography and a deep reactive ion etch process for the fabrication of sub-micron scale diffraction gratings according to an embodiment of the present invention;

FIG. 22 is a plot of experimental data showing absorption characteristics for photovoltaic devices as described with reference to FIGS. 7(AA)-7(CB) and a similar device with no metal underlayer;

FIG. 23 is a plot of the corresponding calculated short circuit current characteristics for the photovoltaic devices as described with reference to FIGS. 7(AA)-7(CB) and a similar device with no metal underlayer.

### DETAILED DESCRIPTION OF THE INVENTION

Hereinafter, embodiments of the present invention are described with reference to the drawings.

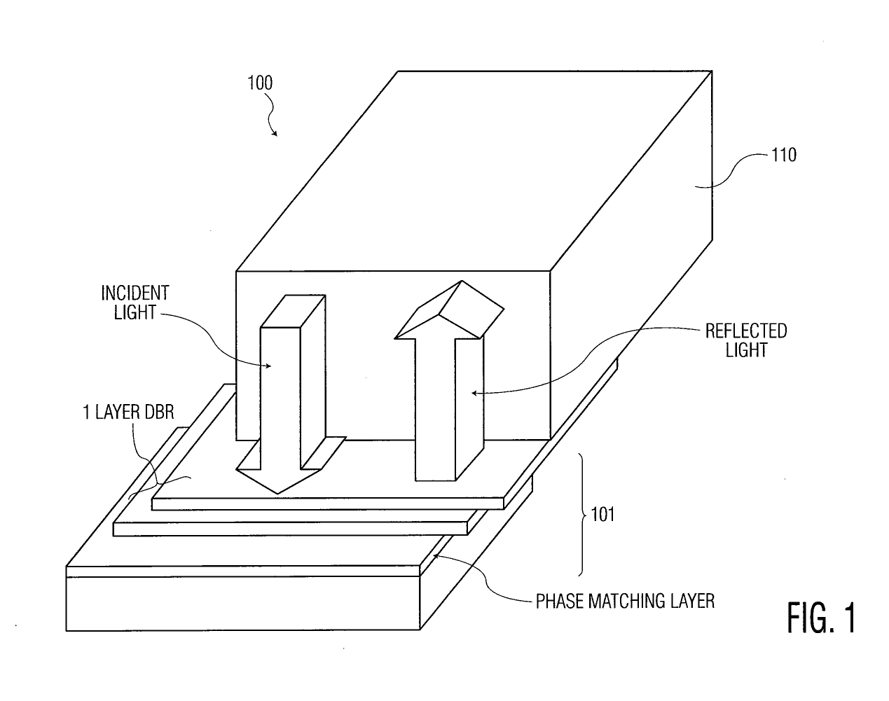

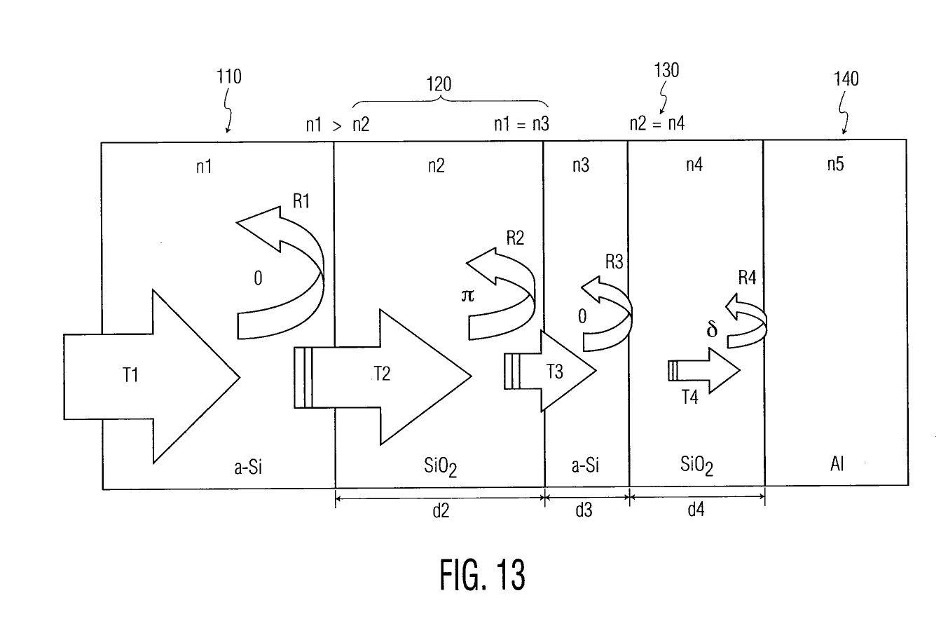

FIG. 1 depicts a schematic of an exemplary photovoltaic device 100 of the present invention and the function thereof. More specifically, FIG. 1 illustrates an incident light wave, which travels through an active photovoltaic material structure 110, and then impinges on a back reflector structure 101. The wave is then reflected by the back reflector structure 101 into the active photovoltaic material structure 110. FIG. 13 is an idealized diagram illustrating this propagation of successively reduced incident light through the photovoltaic layer and through the DBR layer and phase matching layer to the metal layer and back to the photovoltaic layer

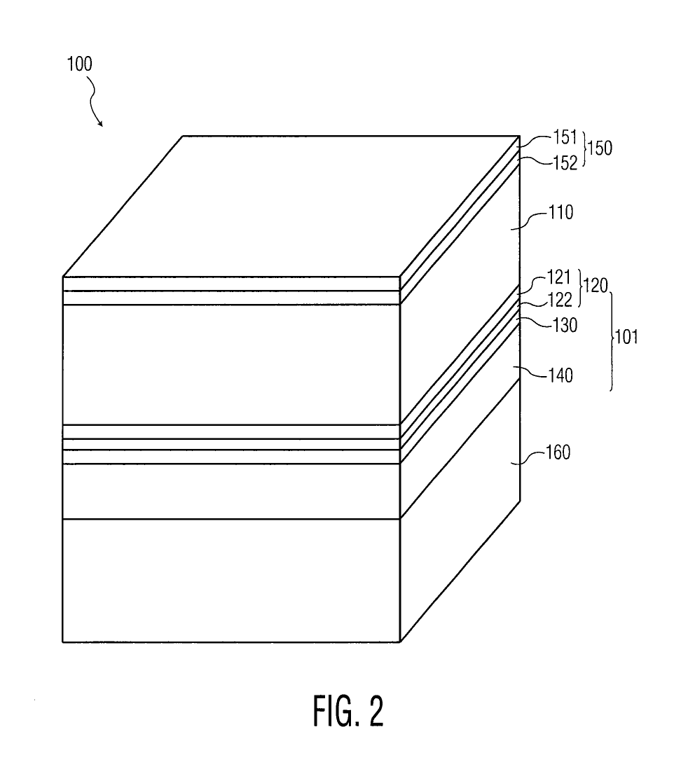

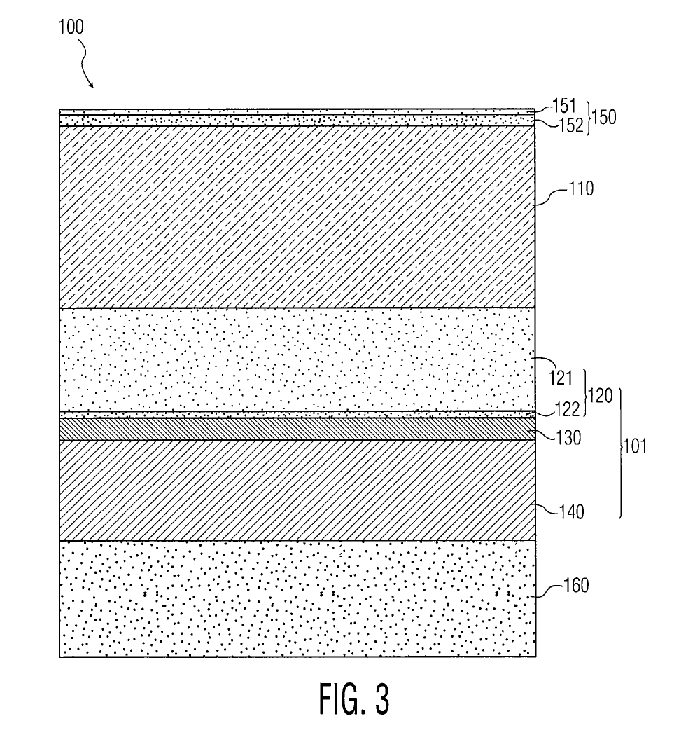

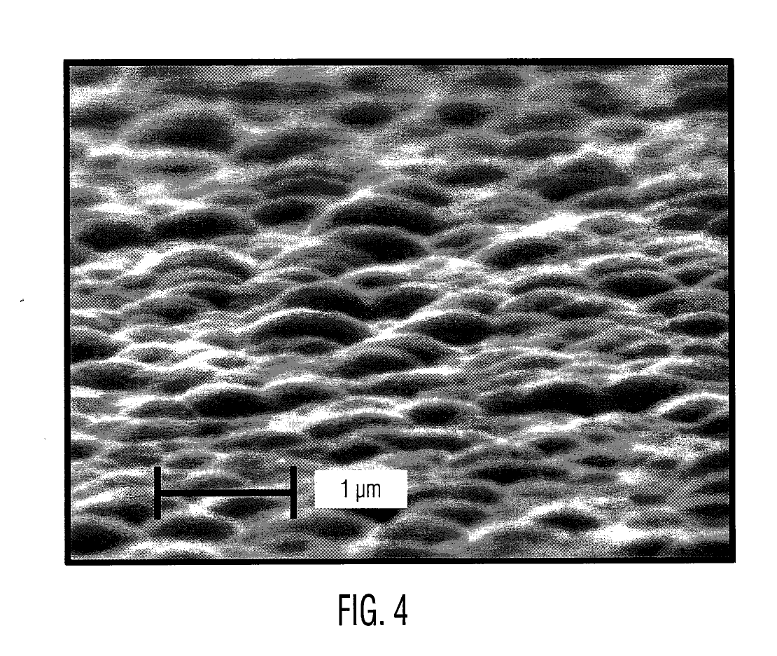

Referring to FIGS. 2-3, photovoltaic device 100 includes photovoltaic layer 110, and a back mirror reflecting layer 101 comprised of a one period DBR layer 120, a phase matching layer 130, a metal layer 140 overlying a substrate 160. Device 100 also includes and an anti-reflective outer layer 150 comprised of sub-layers of silicon dioxide 151 and silicon nitride (Si₃N₄) 152. DBR layer 120, as shown, is a one period DBR, comprised of sub-layers of silicon dioxide 121 and amorphous silicon 122. In other embodiments, the DBR layer may comprise two or three DBR periods. Metal layer 140, aluminum in one exemplary embodiment of the invention, is disposed adjacent the DBR layer 120 and configured to reflect light passed through the photovoltaic layer 110 and the DBR layer 120 back to the photovoltaic layer 110.

Phase matching layer 130, disposed between metal layer 140 and DBR layer 120, is configured to match a phase over a selected wavelength range of incident light. Generally, phase matching layer 130 is comprised of a composition that has a refractive index smaller than the refractive index of the active photovoltaic material used in the photovoltaic layer 110. The phase matching layer may consist of dielectric materials such as SiO₂ and silicon nitride SiNₓ, and any other dielectric material. The phase matching layer may also consist of transparent conducting oxides such as Zinc Oxide (ZnO) or Indium Tin Oxide (ITO), all these transparent conductive oxides may be doped, for example aluminum may be added to the ZnO producing ZnO:Al (aluminum doped Zinc Oxide) In the exemplary embodiments of the present invention, phase matching layer 130 is composed of SiO₂. The appropriate thickness of the phase matching layer 130 may be derived and calculated based on the fundamental Maxwell equations used in conjunction with optimization algorithms, such as the particle swarm optimization algorithm referred to below. The resultant calculated thickness for the phase matching layer 130 in one exemplary embodiment of the present invention is shown, in conjunction with other parameters, in Table 2, referred to below.

In the exemplary embodiment of FIGS. 2 and 3, photovoltaic device 100 further includes a substrate 160 on which metal layer 140 is disposed. Substrate 160 may be made of glass or crystalline silicon or other materials commonly used for such purposed in photovoltaic field. Similarly, the anti-reflective layer may comprise other materials known in the art to be useful for this purpose.

As indicated in idealized FIG. 13, DBR layer 120 is configured to receive light passed through photovoltaic layer 110, to reflect a first portion of the passed light to photovoltaic layer 110, and to pass a second portion of the passed light. Metal layer 140 is configured to receive the second portion of the passed light and to reflect the second portion of the passed light through phase matching layer 130 and DBR layer 120 back to photovoltaic layer 110.

Preferably, the photovoltaic layer 110 comprises amorphous silicon (a-Si), but other active photovoltaic materials, such as: Crystalline silicon (c-Si), nano-crystalline silicon (nc-Si), micro-crystalline silicon (μc-Si), poly crystalline silicon, multijunction polycrystalline solar cells, cadmium telluride (CdTe), copper indium gallium (di)Selenide (CIGS or CuInGaSe₂), dye sensitized solar cells, organic solar cells, gallium indium phosphide (GaInP) or (InGaP), gallium arsenide (GaAs), germanium (Ge) and indium gallium arsenide (InGaAs) may be used.

As is well known in the art, in high performance a-Si solar cells, transparent conductive oxides (TCO) such as indium tin oxide (ITO), tin dioxide (SnO₂) and zinc oxide (ZnO) can serve as a conductive interlayer or as a contact layer. For example, a thin layer of TCO is normally included between the a-Si and the metal layers of conventional a-Si devices to provide a back conductive contact with the a-Si while preventing the formation of interfacial layers that can occur due to the reaction between a-Si and metal.

Electrical contacts in the present invention may be realized at the front and/or back surface of the solar cell. In the case of the front surface, the contacts would exist in the form of a transparent conductive oxide, such as ZnO, SnO2 or ITO, which would then be contacted to a metal grid. In the case of the back surface of the solar cell, the back contact would be integrated with the back surface reflector in a number of ways. One of the integration methods would be by means of etching contact holes through the DBR and phase matching layer. The holes would then be filled with a conductive material such as metal or TCO, so that the back reflecting metal (which also acts as the back surface contact) and active photovoltaic layer can have an electrical conduction path. Another method would be to dope all the DBR and phase matching layers, so that all these layers become conductive and hence, act as a contact between the active photovoltaic material and metal back surface contact (which is also the back surface reflecting metal). Yet another method would be to replace the dielectric DBR layers with TCO layers, for instance replacing the SiO₂ with ZnO or ITO, so as to form a conductive back reflective multilayer stack.

The metal layer in the photovoltaic devices of the present invention may be any metallic material that is suitable for use as a high reflective surface in photovoltaic applications. More specifically, metals or metal alloys or metals with dopants that have high reflective characteristics may be used in the present invention. In the exemplary embodiments described herein, the metal is aluminum.

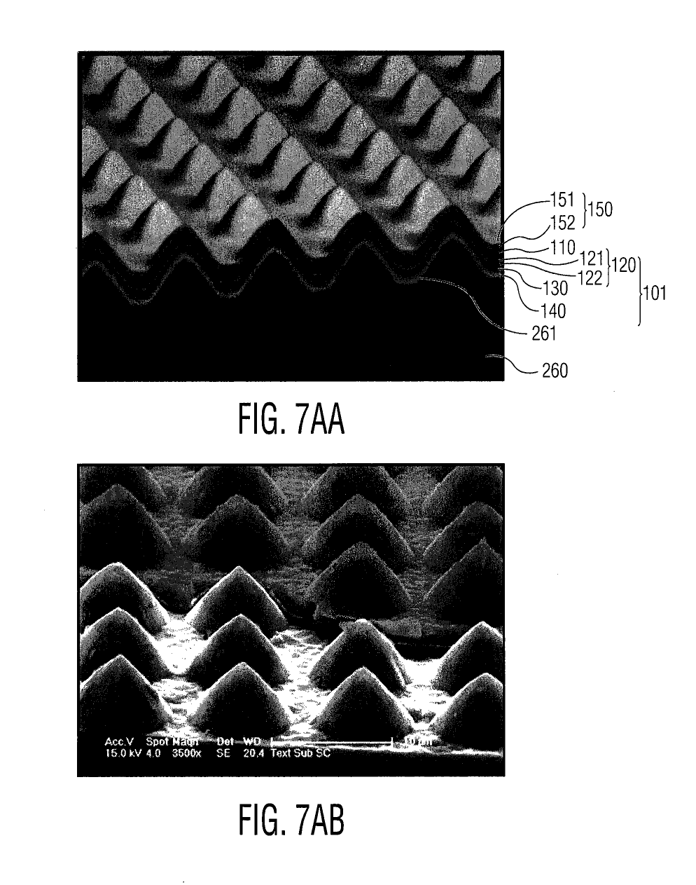

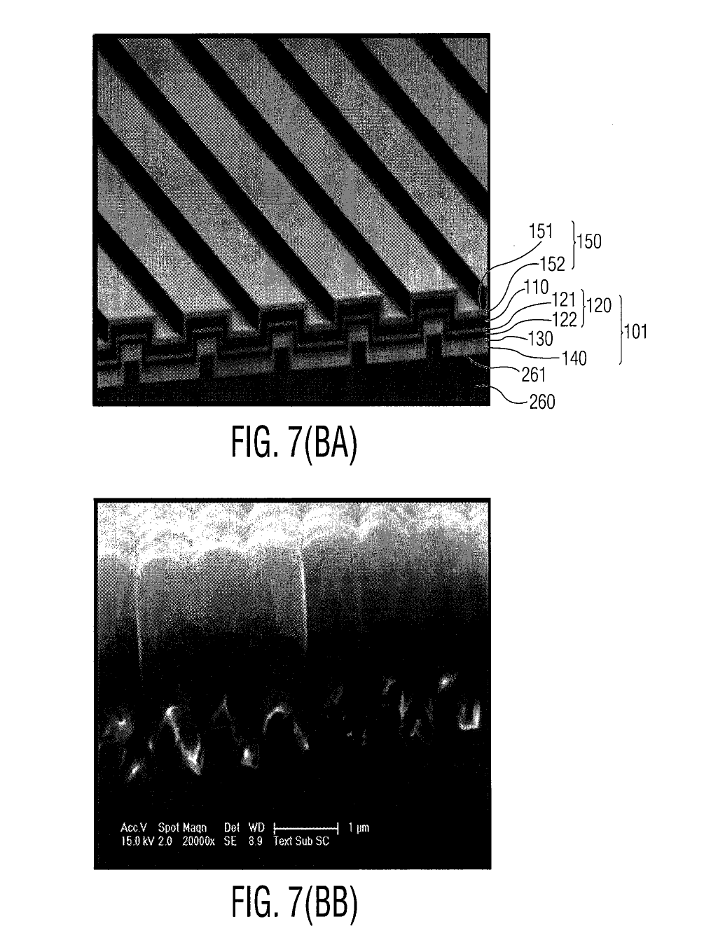

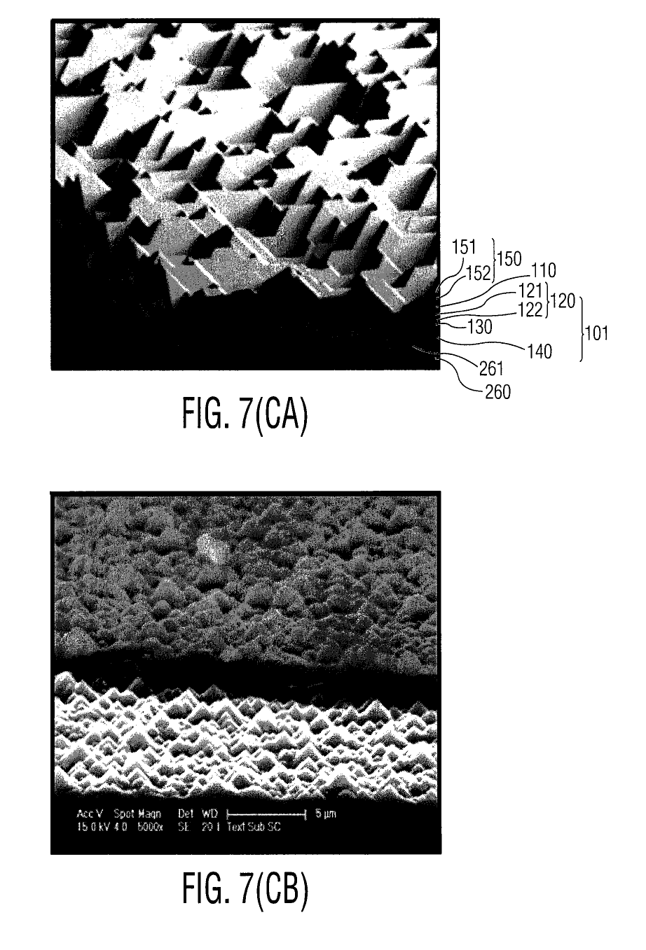

The reflectivity of the metal layer in the photovoltaic device of the present invention is enhanced by surface roughness facing the phase matching layer. This roughness generally comprises a non-uniform surface texture with a multiplicity of raised areas, to which layers overlying the metal layer surface conform, as shown in the SEM image of FIG. 4. The surface actually shown in FIG. 4 is that of the anti-reflectant outer surface of a photovoltaic device, including a photovoltaic underlayer backed by a back surface reflecting structure including a single period DBR layer and metal layer deposited on glass. This roughness may be enhanced by deposition of the metal over a textured substrate surface, as shown in and described with reference to FIGS. 7(AA) to 7(CB).

The width and height of the raised areas of these textured surfaces, as shown in FIG. 4, are generally in the range of a few tenths of a micrometer (μm) to 1 μm.

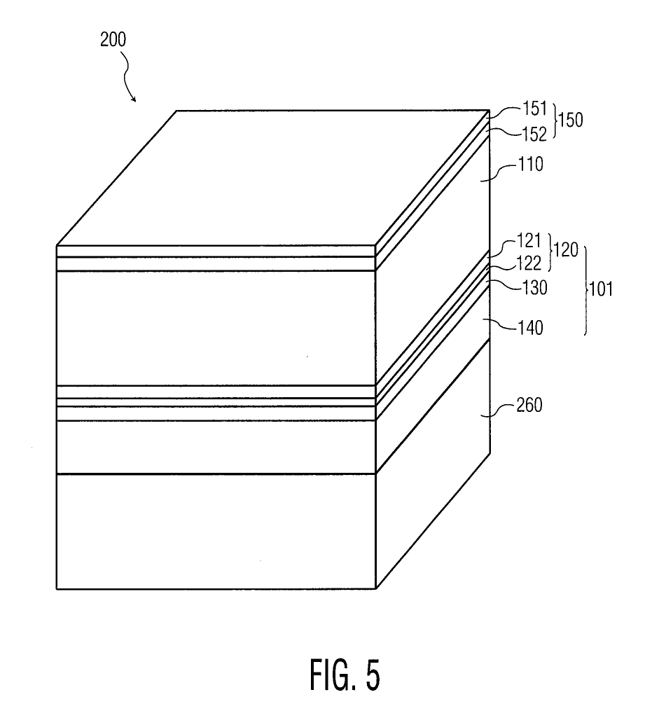

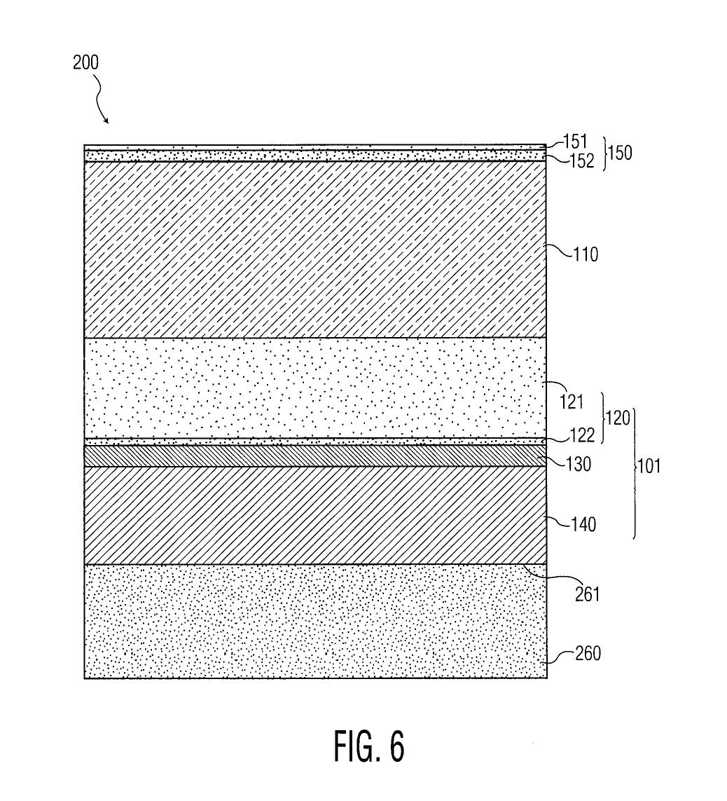

As indicated in the brief description of the figures, FIGS. 5 and 6 depict an embodiment of the present invention like that of FIGS. 2 and 3, but including a crystalline silicon substrate 260, instead of glass.

As shown in FIG. 6 and in FIGS. 7(AA) to 7(CB), substrate 260 may include a textured surface 261 comprised of randomly or regularly raised areas on the surface of the substrate 260 on which the metal layer is deposited, thus producing a conforming surface in the metal layer 140 deposited on substrate 260. Three versions of such surfaces are illustrated in FIGS. 7(AA) to 7(CB)

FIG. 7(AA) is a graphic representation of a photovoltaic device having a regular upright pyramidal (Pymd Struct) textured surface on a c-Si substrate facing the metal layer deposited thereon. FIG. 7(AB) is an SEM image of a photovoltaic device like that graphically shown in FIG. 7(AA). In the upper portion of FIG. 7(AB), the portion of the device shown includes the photovoltaic layer and the antireflective layer overlying the photovoltaic layer. In the lower portion of FIG. 7(AB), some of the overlayers of the device are broken away to reveal the underlying textured substrate. FIGS. 7(BA) and 7(BB) and FIGS. 7(CA) and 7(CB) correspond to FIGS. 7(AA) and 7(AB) respectively, differing only in that the textured surface of the substrate in FIGS. 7(BA) and 7(BB) is a diffraction grating and the textured surface of the substrate in FIGS. 7(CA) and 7(CB) is randomly etched.

In one form or another, the raised areas produced by the textured substrate surface results in raised areas in the overlying metal layer with widths and heights on the order of tenths of a nanometer to 1 micron.

Herein the term “a-Si sub-structure” is sometimes used to refer to structures used for the design, test and fabrication processes of photovoltaic devices like those of the exemplary embodiments described above and to compare such devices to similar devices but lacking one or more elements of those embodiments. For example, an a-Si sub-structure may be a structure (i) having an ARC layer, a photovoltaic layer and a one period DBR layer but having no metal layer at the back of the one period DBR layer; (ii) having two or three period DBR layers; (iii) having a photovoltaic layer only, (iv) having an ARC layer and a photovoltaic layer, only, etc.

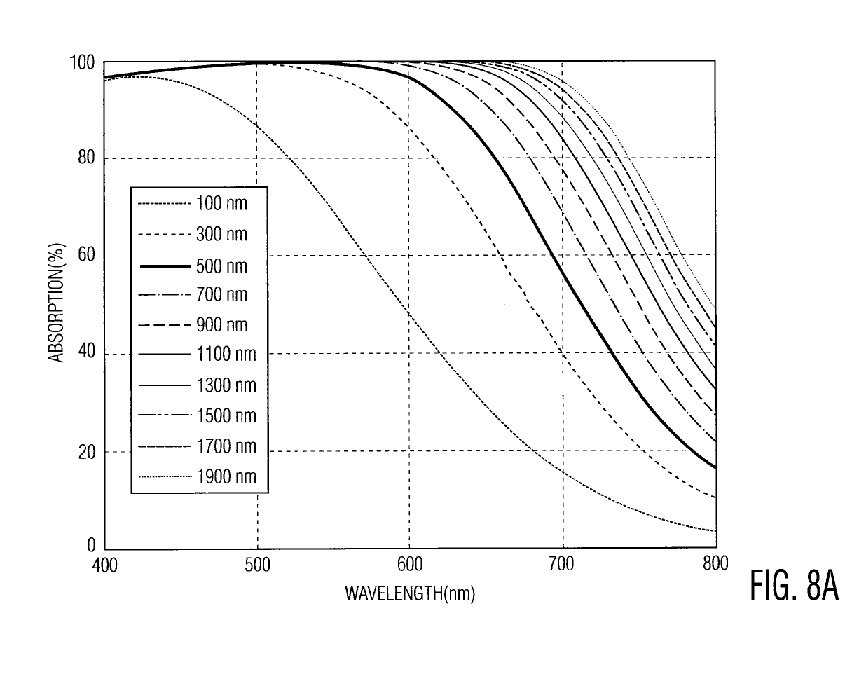

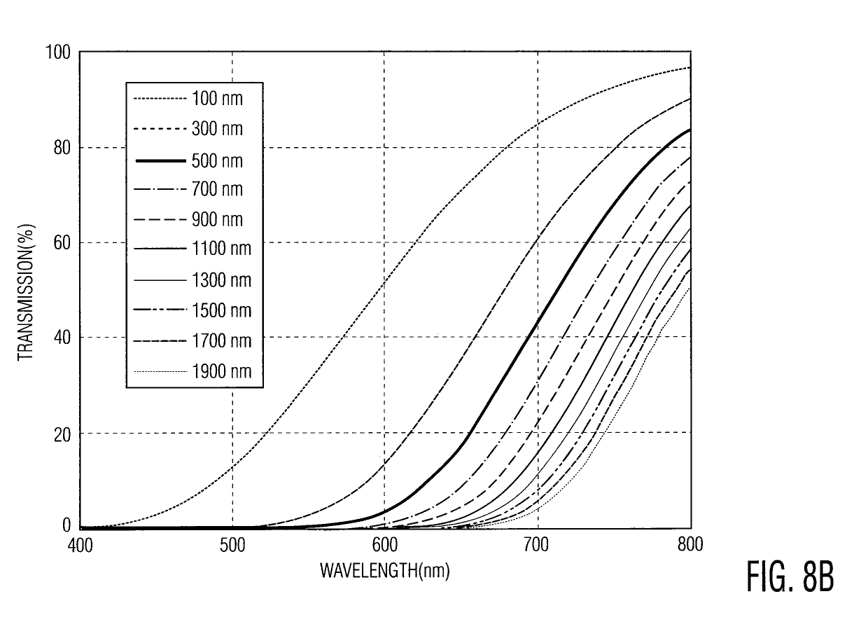

For purposes of optimizing solar devices of the present invention, mathematical simulated and experimental data has been used. The mathematical simulation includes studies of photovoltaic devices as disclosed and claimed herein with a back surface reflector consisting of a single period DBR overlying a phase matching layer, an aluminum metal layer and a crystalline silicon substrate. FIGS. 8(A) and 8(B) graphically illustrate the resultant calculated relationships of absorption characteristics and back reflector transmission characteristics, over a range of wavelengths of light, for a range of photovoltaic layer thicknesses. From these and other studies, 500 nanometers has been selected as the preferred thickness for an amorphous silicon photovoltaic layer in devices of the type exemplified herein. Reasonably effective absorbance and transmissivity is also shown however for thicknesses ranging from 100 nm to 2 μm.

As may be seen in FIG. 8(B), the transmission of light increases significantly at a wavelength of close to 600 nm. Therefore, 600-800 nm has been selected as the design wavelength range for the back reflector.

Another design parameter relevant to the present invention is the selection of the metal used in the reflective metal underlayer. Aluminum is preferred as that metallic layer, because of its well-known utility for this purpose in the photovoltaic industry. Aluminum has been used for a long time as a back reflecting material in many types of solar cells. However the ‘parasitic’ absorption characteristics of aluminum, especially in a-Si solar cells, is very significant. In the present invention therefore, a phase matching layer, typically comprised of SiO₂ separates the metal from the semiconductor or multilayer DBR stack, significantly reducing the amount of light that actually gets absorbed in the metal layer

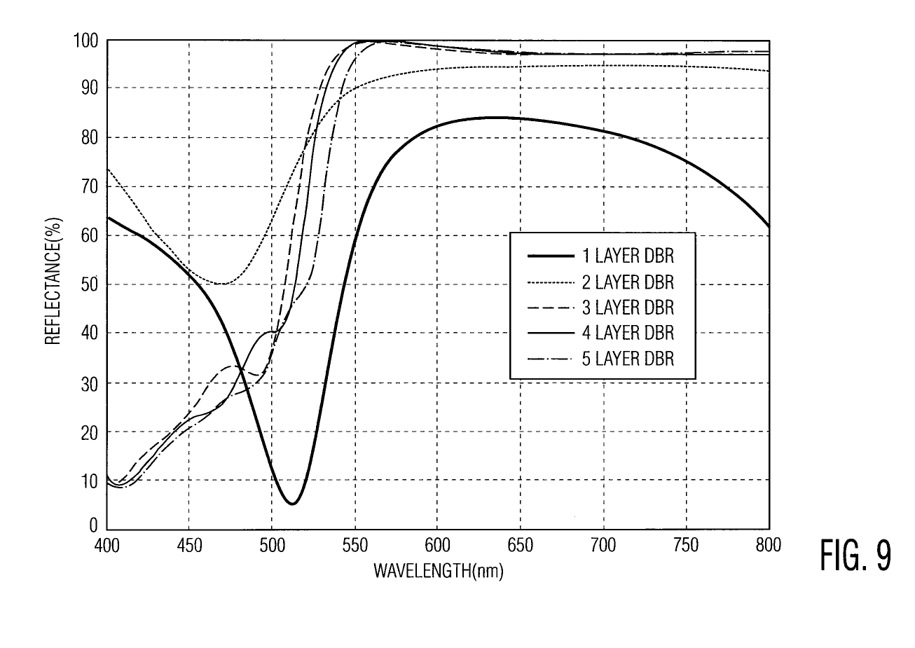

Next, in order to determine the structure of the photovoltaic device reflecting dielectric layers, the multilayer DBR of the back reflector is analyzed to obtain the highest reflectance for the desired wavelength range, 600-800 nm. For this an optimization algorithm, referred as Particle Swarm Optimization or PSO (see Energies, 2010, Volume 3, pages 1914-1933), is applied. This is performed in order to obtain the optimal design parameters, for a varying number of periods in a DBR stack. Each DBR stack is set atop an SiO₂ layer and has a semi infinite a-Si superlayer (cladding layer) forming an a-Si sub-structure with a DBR stack. The reflectance simulation results of the a-Si sub-structure of the DBR stack, with the number of periods in the DBR ranging from one to five, are shown in FIG. 9. It can be seen that only about three layers of DBR are needed to achieve a reflectance that is similar to that of a stack with many more layers of DBR

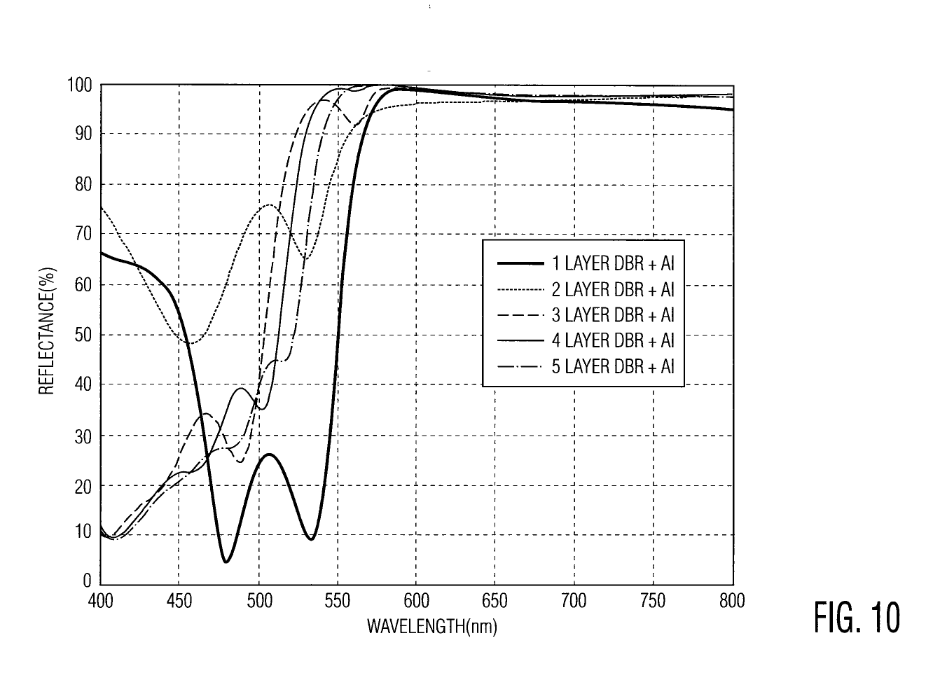

With this observation in tow, the next step is to observe the reflectance characteristics of the DBR structures, with 1 to 5 DBR periods after the addition of a metallic layer with a phase matching layer, i.e., the performance of the hybrid dielectric-metallic back surface reflector as disclosed herein. The resultant data is shown in FIG. 10.

As be seen in FIG. 10, the reflectance characteristics of the various a-Si sub-structures having varying layers of DBR, in the wavelength region of 600-800 nm of interest, are quite similar. It is seen that even the a-Si sub-structure with one DBR period, has a very high reflectance. For that matter, the three period DBR stack, has a reflectance that is almost identical to that of the 4 and 5 period DBR stacks. Of greater interest is the 1 Layer DBR period, which has a reflectance of 97.7% in the range of 600-800 nm. The reflectance of the 1 period DBR is only about 1.1% less than that of the 3 period DBR stack.

The design parameters of the various a-Si sub-structures having varying layers of DBR, in the 1, 2 and 3 Layer DBR structures, are presented in Table 1. The amount of light absorbed in the BSR is minimal, as can be seen by the high reflectance values of the various structures in Table 1. These results show that the absorption, in the otherwise lossy metal, is mitigated by the addition of the dielectric layers, and in turn, the metal increases the overall reflectance.

TABLE 1
The design parameters and performance characteristics of the 1,
2 and 3 layer DBR structures:

| | | | | Avg | Avg |
|---|---|---|---|---|---|
| | DBR: | DBR: | | Reflectance | Reflectance |
| | Thick- | Thick- | Phase | (%) | (%) (Wave- |
| | ness | ness | matching | (Wave- | length: |
| a-Si | of SiO₂ | of a-Si | layer: | length: 600- | 600-800 |
| sub- | Layer | Layer | Thickness | 800 nm) | nm) with |
| Structure | (nm) | (nm) | (nm) | no metal | Aluminum |
| 1 Layer | 345 | 36 | 147 | 80 | 97.7 |
| DBR | | | | | |
| 2 Layer | 118 | 38 | 150 | 96 | 98 |
| DBR | | | | | |
| 3 Layer | 137 | 32 | 172 | 98.4 | 98.8 |
| DBR | | | | | |

The absorption in the entire BSR of the photovoltaic device, Abs_{BSR}, can be calculated by subtracting the percentage reflectance, Ref_{BSR}, and transmittance, Trans_{BSR}, from 100%, as is shown in Eq. (1). The resultant absorption for the 1 layer DBR structure of the a-Si sub-structure with no metal is 2% (600-800 nm), and 2.3% with the addition of the aluminum layer and the phase matching layer. This means that the addition of the aluminum layer increases the back reflector losses by 0.3%, in the 600-800 nm range.

Abs_{BSR}=100−Ref_{BSR}−Trans_{BSR} (1)

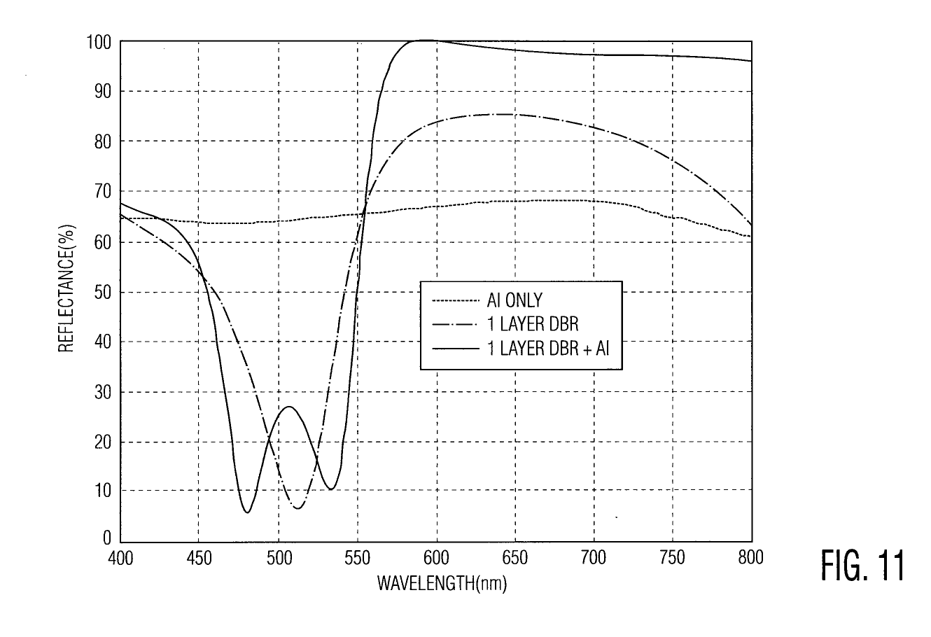

To put the performance of the 1 Layer DBR into context, the reflectance characteristics of the a-Si sub-structures with (i) an aluminum layer only, (ii) a 1 Layer DBR only, and (iii) a 1 Layer DBR with an added aluminum layer are plotted, as shown in FIG. 11. These structures reflect the light into a semi infinite a-Si cladding layer (layer on top of reflector). The benefits of adding the aluminum layer to the 1 Layer DBR are clearly visible, especially in comparison to the reflectance characteristics of the plain aluminum layer. The reflectance, in the 600-800 nm range, of the aluminum only structure is 66%, that of the one period DBR structure is 80%, and that of the 1 Layer DBR with the added aluminum layer is 97.7%.

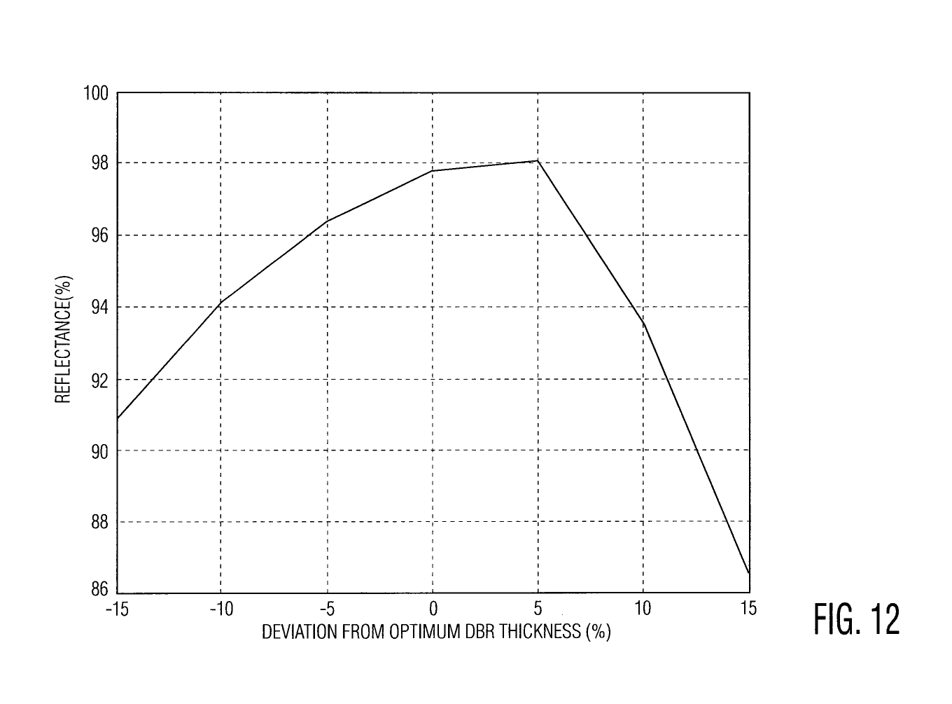

Furthermore, a tolerance analysis of the a-Si sub-structure with the 1 Layer DBR structure by altering the thickness of each layer included in the dielectric back reflector assembly, by ±5%, ±10% and ±15%, respectively, was performed, as shown in FIG. 12. The bandwidth to 590-800 nm was broadened slightly, to further give an idea of the robustness of the dielectric reflector. As is seen in FIG. 12, the reflectance characteristics remain above 90%, for a design tolerance of 0% to −15%. In the positive direction, it is seen that the reflectance is more affected at the extremity, +15%, where the reflectance drops to about 86%. All in all, the reflectance values stay above 90%, in the tolerance range of −15% to about +12%.

The governing physical behavior of the hybrid dielectric-metallic back reflector of the present invention can be described using the theory of reflection and transmission of light waves at multiple interfaces, as is depicted in FIG. 13. If considering a light wave, T1, that is incident through the a-Si active layer, as is shown in FIG. 13, as it impinges on the first SiO₂ layer in the DBR, a portion of the incident power, R1, gets reflected and the rest, T2, is transmitted. The exact magnitudes of R1 and T2 can be deduced using Fresnel formulae. The wave reflected off the n1/n2 interface, R1, does not experience a phase change, since n1>n2.

The transmitted wave, T₂, traverses through the SiO₂ layer and onto the n₂/n₃ interface, where again part of it is reflected, R₂, and the rest transmitted, T₃. Since n₂<n₃, R₂ experiences a π phase shift on reflection at the n₂/n₃ interface. As R₂ travels through the SiO₂ layer, a distance of 2d₂, it picks up a roundtrip phase shift, in addition to the π phase change on reflection from the n₂/n₃ interface. Therefore, the relative phase shift of the two reflected waves, i.e. R₁ and R₂ is given by the difference between the change in phase experienced by R₁ and the total roundtrip phase change experienced by R₂ (which includes the π phase shift from the n₂/n₃ interface). If this relative phase difference is an integral number of wavelengths, then constructive interference occurs.

The portion of wave that hits the back aluminum layer experiences a phase change that is not quite equal to π because of the lossy nature of the metal, δ<π for all wavelengths. Hence the need for a layer that ensures that the waves reflected off the n3/n4 and n4/n5 interfaces are in phase, i.e., R3 and R4 are in phase. This layer is the phase matching layer which is depicted in FIG. 13, as having a thickness of d₄.

It should be noted that most analytical treatments that provide optimal parameters for the maximum reflectance of such an arrangement, consider mainly single or small wavelength bands. In practice however, when considering broadband illumination, such as sunlight, optimization algorithms and electromagnetic simulation tools to obtain the optimal design parameters need to be used. To this end, the particle swarm optimization and S-Matrix algorithms have been employed to optimize the design parameters over the entire wavelength region of interest.

To determine suitable fabrication techniques in accordance with the present invention, four a-Si sub-structures have been studied. The first, referred to as ‘a-Si Only’, consists of a single layer a-Si, deposited on a glass slide. The second a-Si sub-structure has an ARC, added to an a-Si layer, and it is referred to as ‘ARC+a-Si’. The third a-Si sub-structure, adds 1 layer DBR interposed between the substrate and the a-Si layer, and is referred to as ‘ARC+a-Si+1 Layer’. The last includes an aluminum layer and phase matching layer interposed between the substrate and the DBR layer and is referred to as ‘ARC+a-Si+1 Layer+Al’. All the design parameters, for all the various components, of the four structures are specified in Table 2.

TABLE 2
Summary of optimal design parameters for the fabricated solar
cell a-Si sub-structures.

| a-Si sub-Structure | Design Parameters (in nm) |
|---|---|
| ARC (SiO₂) | 10 |
| ARC (Si3N4) | 62 |
| a-Si active layer | 500 |
| 1 Layer DBR (SiO₂) | 345 |
| 1 Layer DBR (a-Si) | 36 |
| Phase matching | 147 |
| Layer | |
| Aluminum Layer | 4000 |

These four a-Si sub-structures all include a 500 nm a-Si layer and all fabricated on glass slides. In the a-Si sub-structures which incorporate an aluminum layer, the aluminum is deposited first on the glass slide, using electron beam evaporation. All the other layers are deposited on top of the aluminum layer, using plasma enhanced chemical vapor deposition (PECVD). The a-Si sub-structures that have no aluminum are directly deposited on the glass slides using PECVD. The configuration of these a-Si sub-structures corresponds to the “substrate” optical design, where sunlight enters the solar cell before it reaches the substrate, which is outlined in Handbook of Photovoltaic Science and Engineering, Wiley, 2003, pp. 505-565.

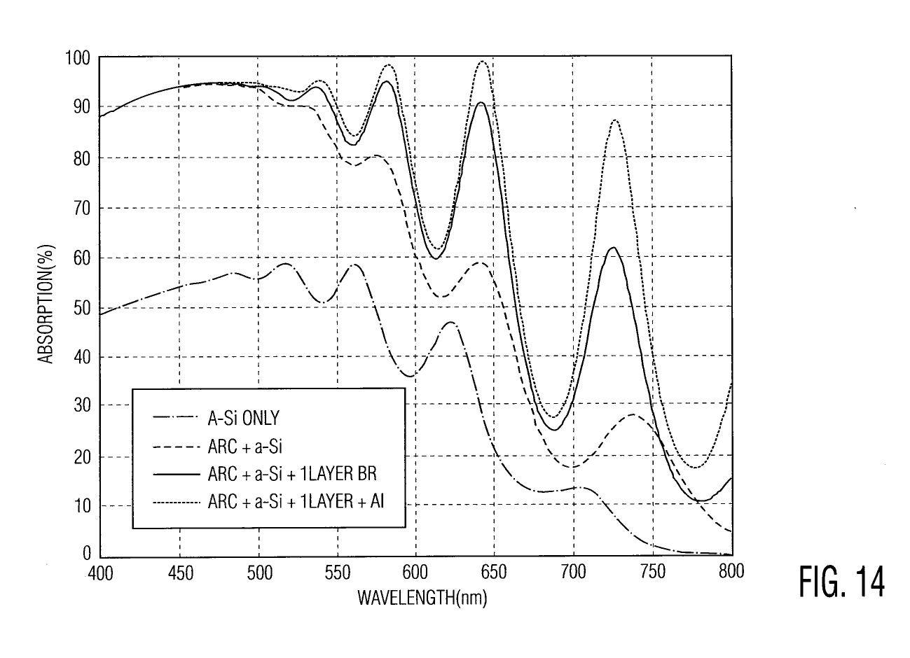

The calculated absorption characteristics, of devices with the four a-Si sub-structures described, are graphically shown in FIG. 14. As the back reflectors are added, Fabry-Perot resonance peaks are seen to occur at wavelengths as described by the following equations.

$${λ}_{m} = \frac{2 n t}{m} \qquad ( 2 )$$

where n is the refractive index, and t is the thickness of the active solar cell material (a-Si), and m is an integer.

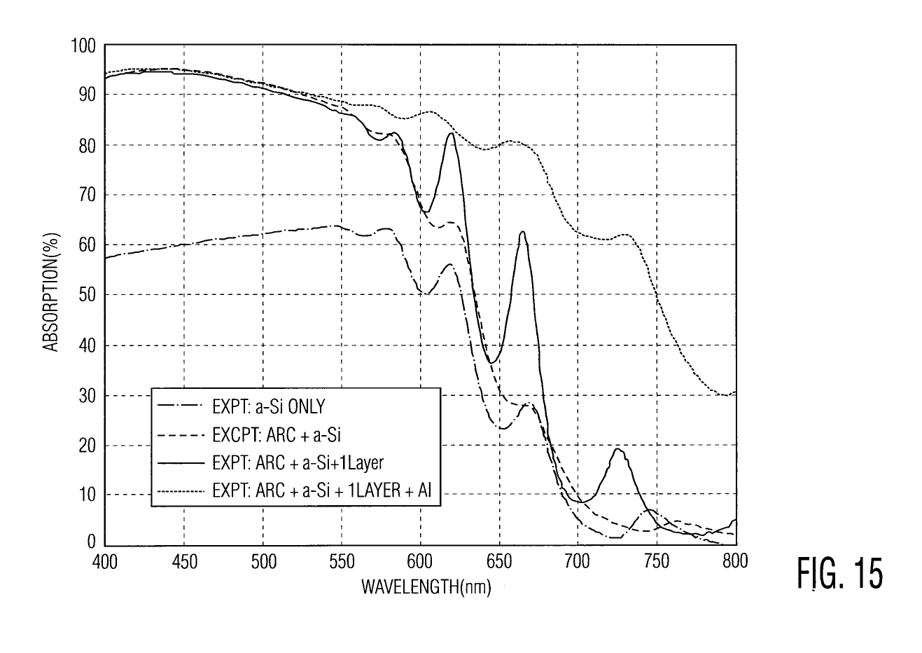

The reflection and transmission characteristics of devices fabricated with a-Si sub-structures have been mathematically simulated and characterized, using a spectrophotometer fitted with an integrating sphere. To calculate absorption, an equation similar to Eq. (1) was used, only this time, the absorption, reflection and transmission characteristics, were for the fabricated a-Si sub-structures, which all included a 500 nm a-Si layer. The corresponding average absorption values in the range of 400-800 nm are tabulated in Table 3. These values, as simulated and as measured, are plotted in FIGS. 14 and 15, respectively.

TABLE 3
Final values of the average absorption for different a-Si sub-
structures over the entire 400-800 nm range.

| | Avg Absorption (%) | Avg Absorption (%) |
|---|---|---|
| a-Si sub-Structure | Simulation | Experimental |
| a-Si Only | 38 | 41 |
| ARC + a-Si | 63 | 58 |
| ARC + a-Si + 1 Layer | 71 | 61 |
| ARC + a-Si + 1 Layer + Al | 76 | 80 |

The absorption characteristics of fabricated devices with various-Si sub-structures as depicted in FIGS. 14 and 15, show a number of physical phenomena that are worth noting. As shown in the dotted line plot of FIG. 14, with the addition of the 1 layer DBR accented absorption peaks at 620, 670 and 725 nm are clearly present. The peaks correspond to Fabry-Perot resonance frequencies, due to the fact that the planar a-Si layer, with a reflector on one side, forms a Fabry-Perot etalon. The addition of a better reflector at the back surface serves to increase the height of the peaks, at the same wavelengths. In the plot of FIG. 15, the increased peaks are also present but the peaks are ‘smoothened’, as compared to what is expected from the simulation. The drastic dips in absorption that show up in the simulation results of FIG. 14 are not seen in FIG. 15.

To account for this discrepancy, a closer study of the fabricated structures, using a scanning electron microscope (SEM) reveals that the a-Si sub-structure without an aluminum sub-layer is mostly planar; whereas, the a-Si sub-structure with the aluminum layer has a very rough surface morphology, as is shown in FIG. 4 and discussed in previous paragraphs.

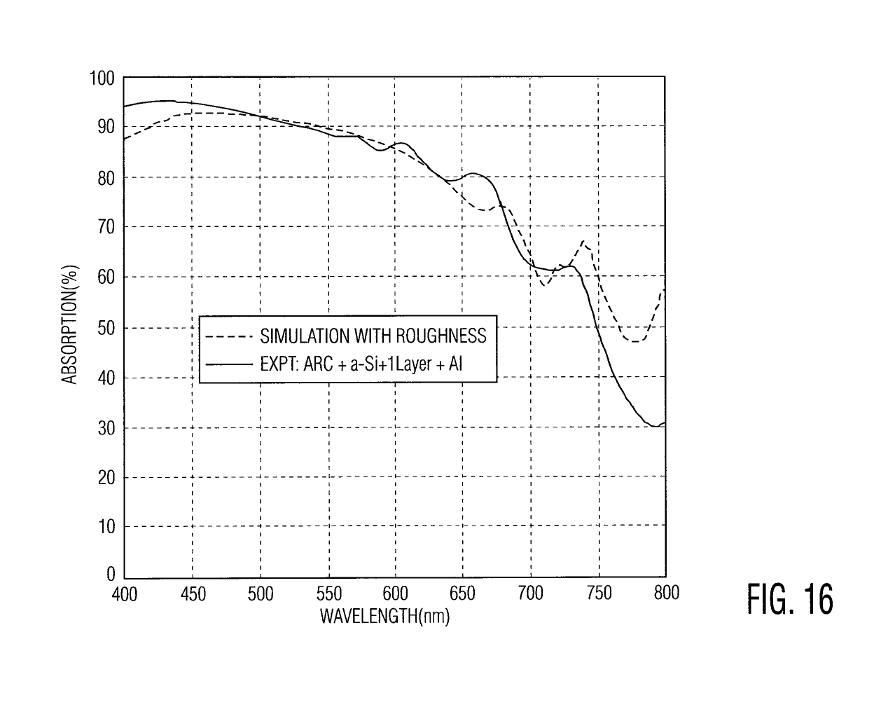

This surface roughness was incorporated, after this observation, into the simulation code by altering the design geometry of the a-Si sub-structures of the photovoltaic device to include raised areas. This mimics the structure of the photovoltaic device shown in the SEM image of FIG. 4. Since the raised areas, as shown in FIG. 4, are of random size and shape, this was simulated by assuming raised area heights varying in size from 70 nm to 150 nm, in increments of 25 nm, and widths of raised area varying from 100 nm to 700 nm, in increments of 100 nm. It is observed in the SEM image of FIG. 4 that the roughness of the outer surface of the device appears to conform to the roughness of the underlying aluminum layer. The average of the results from all the simulations is then plotted as shown in FIG. 16. With this improvement in the mathematical simulation process, a much better correlation between the simulation results with roughness, and the fabrication results of the photovoltaic device, was observed, as compared to the previous simulations that did not incorporate roughness (FIG. 15). The simulation result with roughness, and the fabrication results are compared in FIG. 16 and Table 4. Hence the data demonstrates that the roughness of the aluminum layer is translated throughout the structure of the photovoltaic device, and in turn improves the absorption characteristics of the device.

TABLE 4
Final average absorption values for the structure with an ARC,
1Layer DBR, aluminum and phase matching layer. The table compares
the experimental results with the simulation that incorporates roughness.

| | Avg Absorption (%) | Avg Absorption |
|---|---|---|
| | Simulation | (%) |
| a-Si sub-Structure | with Roughness | Experimental |
| ARC + a-Si + 1 Layer + Al | 80.2 | 80 |

To quantify the improved absorptivity of devices of the present invention as compared to devices similar to those of the invention but lacking elements of the invention, an enhancement factor was computed. The enhancement factor is a comparison of the absorption characteristics of the modified a-Si sub-structures, to that of a a-Si sub-structure with no light trapping enhancement (a-Si only), as shown in Eq. (3).

$$EF ( λ ) = \frac{{\int }_{λ}^{λ = 800} {A}_{E} ( {λ}^{′} ) Irrd ( {λ}^{′} ) d {λ}^{′}}{{\int }_{λ}^{λ = 800} {A}_{s} ( {λ}^{′} ) Irrd ( {λ}^{′} ) d {λ}^{′}} \qquad ( 3 )$$

where the value A_{E} represents the absorption characteristics of an enhanced structure, i.e., with light trapping incorporated, A_{S} represents the absorption of a structure with no light trapping, i.e., the a-Si only structure.

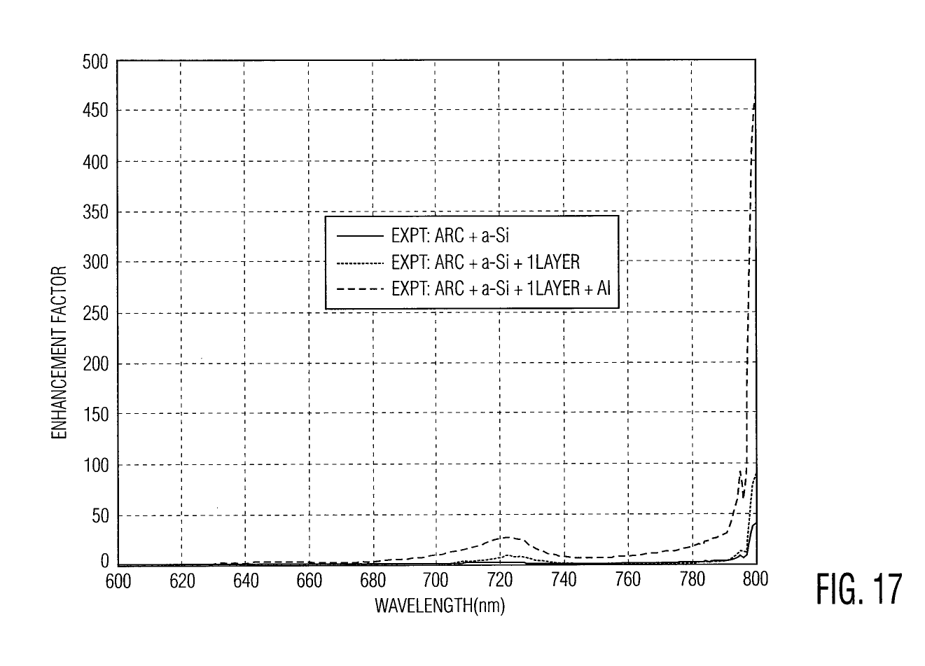

FIG. 17 shows the plotted enhancement factor characteristics for devices of the present invention versus devices lacking one or more elements of the invention over a wavelength range from 600 to 800 nm. It shows that the a-Si sub-structure with the added aluminum layer enhances absorption by more than 400 times, at a wavelength of about 800, nm as compared to a substructure of a-Si only. The average enhancement factor characteristics for all the a-Si sub-structures considered in studies of this invention are tabulated in Table 5.

TABLE 5
Enhancement factor of the different design a-Si sub-structures
considered in studies of this invention.

| | Enhancement Factor | Enhancement Factor |
|---|---|---|
| a-Si sub-Structure | (400-800 nm) | (600-800 nm) |
| a-Si Only | 1 | 1 |
| ARC + a-Si | 1.8 | 2.1 |
| ARC + a-Si + 1 Layer | 2.4 | 3.4 |
| ARC + a-Si + 1 Layer + Al | 9 | 16 |

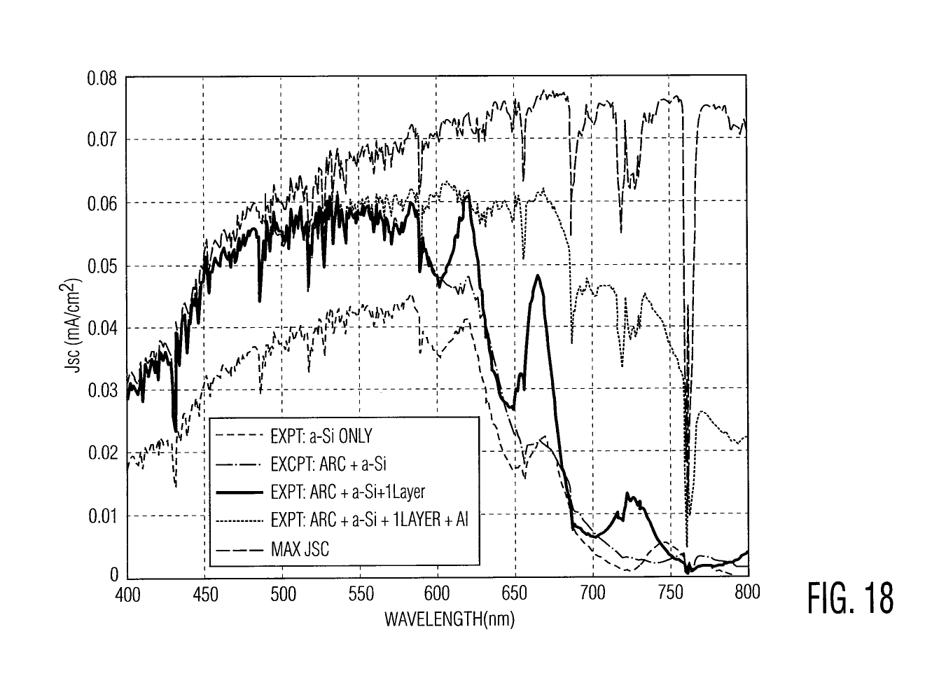

Next, to put this invention into greater context, the short circuit current characteristics, J_{sc}, is calculated for the fabricated devices with the various a-Si sub-structures described above. The J_{sc} is given by Eq. (4)

$${J}_{sc} = \frac{q}{hc} {\int }_{λ}^{ } {λ}^{′} A ( {λ}^{′} ) Irrd ( {λ}^{′} ) d {λ}^{′} \qquad ( 4 )$$

where J_{sc} is the short circuit current density, q is the charge on an electron, h is Planck's constant, c is the speed of light, λ is the wavelength, A is the absorption of the silicon structure and Irrd is the solar irradiance spectrum. It is worthwhile to note that in this calculation the conversion efficiency is taken to be one. The internal carrier collection efficiency is not considered, and hence this gives the upper-bound of the current that can be collected from such a-Si sub-structures. The J_{sc} results are tabulated in Table 6, and plotted in FIG. 18.

TABLE 6
Short circuit current characteristics (J_{sc}) of the different
designed a-Si sub-structures considered in this invention.

| | Jsc (mA/cm²) |
|---|---|
| Structure | (400-800 nm) |
| a-Si Only | 9.4 |
| ARC + a-Si | 13.2 |
| ARC + a-Si + 1 Layer | 14 |
| ARC + a-Si + 1 Layer + Al | 19.3 |
| Maximum J_{sc} | 25.6 |

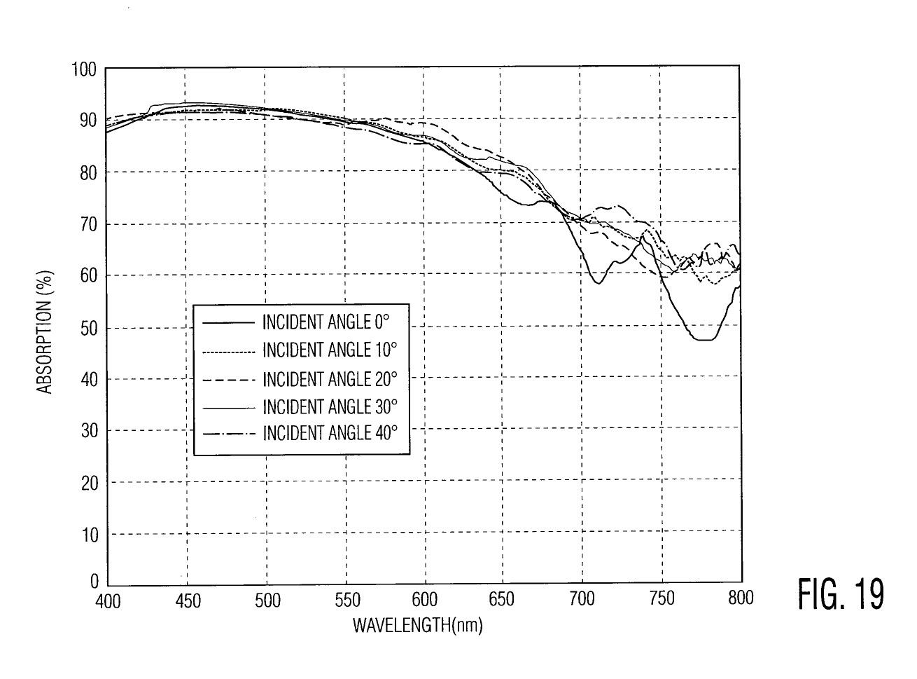

The performance of the structure of the photovoltaic device having the 1 DBR layer under illumination at different angles of incident light has also been calculated. The starting angle is zero degrees (at which the incident light is normal or perpendicular to the photovoltaic surface) and then the angle goes all the way up to 40 degrees, with increments of 10 degrees in between. The results from this calculation are shown in FIG. 19 and Table 7. It can be seen that the absorption increases as the incident angle is increased, which is a good sign of the versatility of the structure of the photovoltaic device of the present invention.

TABLE 7
The performance of the structure with an ARC, 1Layer DBR and
an aluminum layer with a phase matching layer, at different angles
of incident light.

| Incident Angle | (in J_{sc} in mA/cm² for ARC + a-Si + 1 Layer + Al |
|---|---|
| degrees) | structure |
| 0 | 80.2 |
| 10 | 82 |
| 20 | 82.2 |
| 30 | 82.4 |
| 40 | 82 |

Photovoltaic devices with c-Si substrates having textured surfaces as shown in FIGS. 7(AA)-7(CB) enhance the optical light trapping properties of amorphous silicon solar cell structures, providing a number of avenues that can be used to enhance the performance of thin film solar cells.

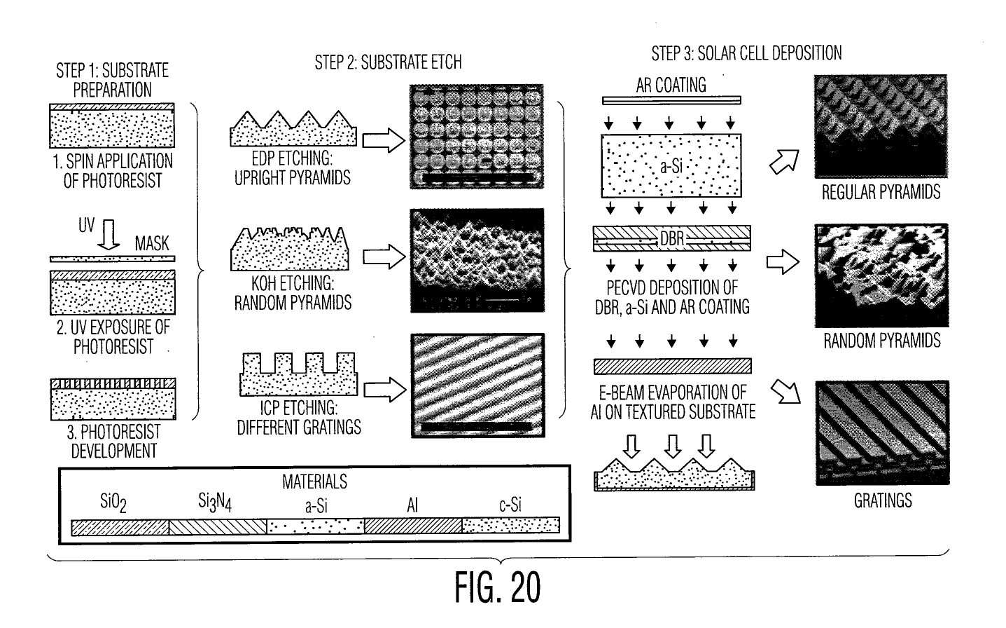

To achieve the various substrate textures, three distinct texturing methods are employed, each one producing a different substrate morphology. These techniques are, nano-texturing of regular diffraction gratings using ICP (Inductively Coupled Plasma) etching, EDP (Ethylene Diamine Pyrocatechol) etching of regular upright pyramids and KOH etching of random pyramids. After the etching processes, the aluminum layer (for the back reflector) is deposited using e-beam evaporation; PECVD (Plasma Enhanced Chemical Vapor Deposition) is then used to deposit all other layers. The phase matching layer is deposited first using PECVD, which is then followed by the single period DBR. Next comes the deposition of the a-Si solar cell layer, which is followed by a double layer ARC (SiO₂/Si₃N₄), all as shown in FIG. 20.

In one exemplary embodiment, the random pyramids of the textured c-Si substrate are realized by etching the c-Si samples in an aqueous solution of 10% (w/v) KOH, with 2% of the final solution consisting of isopropanol (IPA). The solution is heated to 75 degrees Celsius after which the c-Si samples are immersed in the solution for 20 minutes. The resultant surface is covered with random and irregular pyramids, which average less than 1 microns in size.

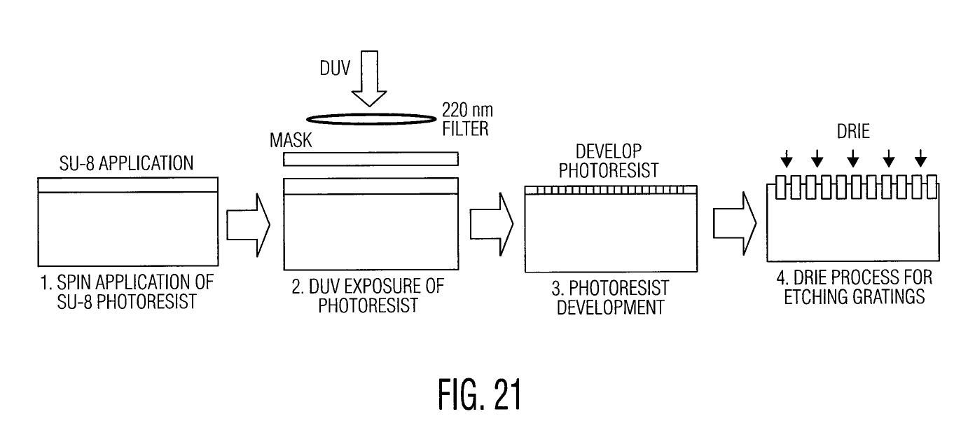

In another exemplary embodiment, the diffraction gratings of the textured c-Si substrate are produced using a more elaborate process than the other textured substrate processes. The period of the gratings is 864 nm with a 50% fill factor. This requires the use of deep ultra violet (DUV) lithography. This lithography process is carried out using SU-8 photoresist which is specialized for i-line (365 nm) photolithography, and hence the process is tailored to fit the resist characteristics. The use of SU-8 2000.2 results in a thickness of 200 nm when spun at 3000 rpm. The exposure of the resist is carried out using a 220 nm exposure wavelength, with an exposure dose of 30 mJ/cm²; to get the exact dose of DUV light, a 220 nm light filter is placed on top of the mask during the exposure process. The developed resist in turn acts as an etch mask for a deep reactive ion etch (DRIE), which is used to realize the gratings, as shown in FIGS. 20 and 21 and in FIGS. 7(BA) and 7(BB).

In another exemplary embodiment, the regular upright pyramids of the textured c-Si substrate are realized using a photolithography process with a light filled pyramid (mesh) mask, using a positive photoresist (Shipley—S1813). The S1813 resist also serves as the etch mask for the EDP etch. The EDP etch solution is prepared (as outlined in S. Sriram and E. P. Supertzi, “Novel V-groove structures on silicon,” Appl. Opt. 24, 1784-1787 (1985) http://www.opticsinfobase.org/abstract.cfm?URI=ao-24-12-1784 and Y Backlund and L Rosengren, “New shapes in (100) Si using KOH and EDP etches.” J. Micromech. Microeng. 2, 75 (1992)) after which the c-Si substrate is immersed in the solution for 10 minutes. Following the etch process, the c-Si sample is rinsed in DI water for 2 minutes. The result of the etch process is the formation of regular upright pyramids, as can be seen in FIG. 20 and in FIGS. 7(AA) and 7(AB).

For the devices tested, as described herein, the fabrication techniques described in the preceding paragraphs were used. The rest of the layers of the photovoltaic devices having these differently textured c-Si substrates were deposited on each c-Si substrate in the same way. This ensured that all the parameters of the solar cell structures would be the same. In addition, a photovoltaic device with layers deposited on a planar glass slide was fabricated for comparison with the structures on the textured c-Si substrates. Upon comparison of all of these devices, it was concluded that t he surface of the device with the textured c-Si substrate that resulted from deposition on the random pyramid surface (Random Pymd) consisted of an aggregation of semi spherical micron scale structures, as shown in FIG. 7(CB). The surface structure of the photovoltaic device with gratings (Grating Samp) on the substrate, as shown in FIG. 7(BB), conformed only generally to the underlying grating, more specifically forming columnar shaped structures that coalesced to form a surface with gentle semi circular ridges over the gratings. The outer surface of the photovoltaic device deposited on the regular pyramids (Pymd Struct), as shown in FIG. 7(AB), conformed well to the underlying substrate.

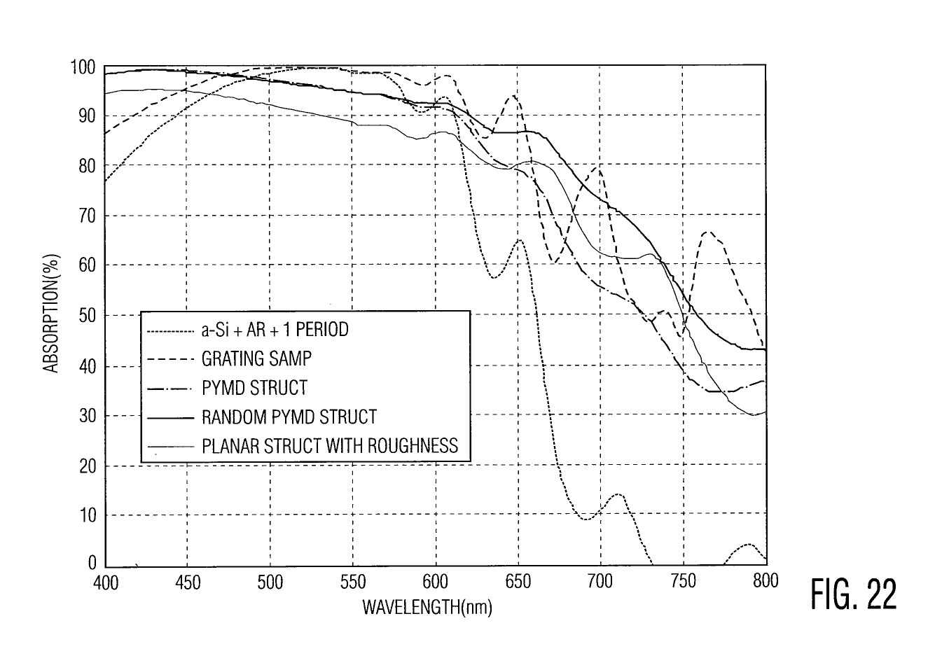

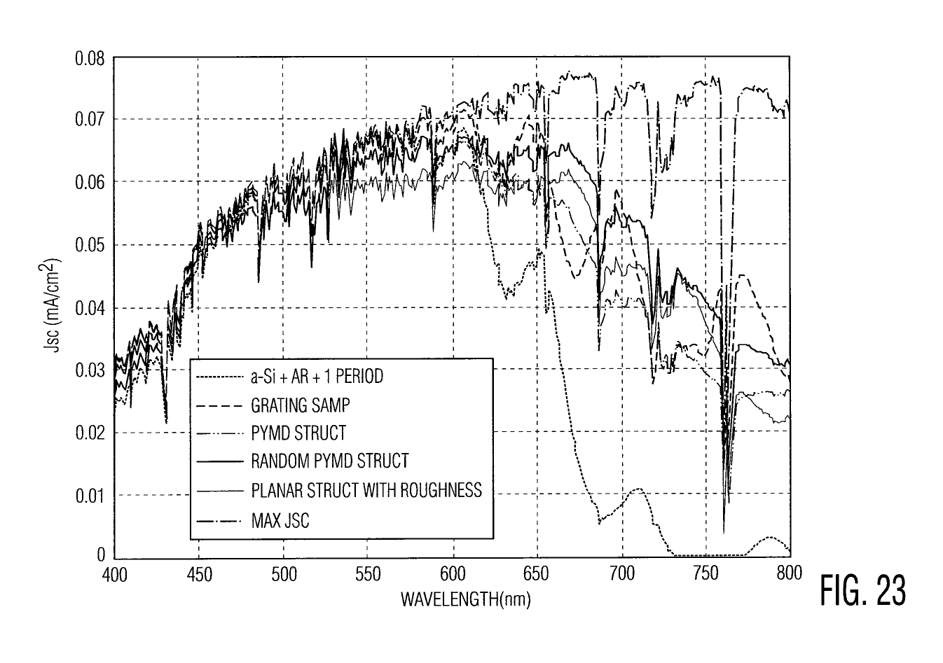

All structures of photovoltaic devices with textured c-Si substrates were fabricated with the parameters shown in Table 2 and characterized using a Perkin Elmer lambda 750 spectrophotometer, fitted with an integrating sphere. FIGS. 22 and 23 show the resultant experimental absorption characteristics and calculated short circuit current characteristics of the structures the photovoltaic device with the textured c-Si substrate as illustrated in FIGS. 2-4 and FIGS. 7(AA)-7(CB), with an assumed quantum efficiency of 1. Also included in FIG. 22 is the absorption data of the structure (Planer Structure with Roughness) of the photovoltaic device having a glass slide substrate (ARC+s-Si+1 DBR layer+Al) from FIG. 15 for comparison. The resultant absorption and short circuit characteristics for the various structures of the photovoltaic device are summarized in Table 8.

TABLE 8
Summary of the light trapping performance of the various
structures of the photovoltaic device presented in the embodiments
of the present invention.

| Structure | Absorption (%) | Jsc (mA/cm²) |
|---|---|---|
| a-Si + AR + 1 Period | 60 | 14.6 |
| Planar Struct with Roughness | 80 | 19.3 |
| Pymd Struct | 78 | 19.4 |
| Random Pymd Struct | 83 | 21 |
| Grating Samp | 83 | 21 |

The structure with the grating (Grating Samp) and the one with the random pyramidal surface (Random Pymd Struct) perform at par, in terms of their average absorption. This means that one does not have to use the elaborate nano-texturing technique to achieve a high light trapping capacity in thin film a-Si solar cells. Rather, a good randomly textured pyramidal surface (of the substrate) will suffice, which is of course much easier to fabricate. The Random Pymd and Grat Samp structures of the textured c-Si substrate have the highest absorption characteristics, which are to be expected due to the small width and height of the textured features of the substrate.

While this invention has been described with reference to its incorporation in photovoltaic devices, such as, a-Si solar cells, it can be easily adapted to many other thin film solar cell device technologies.

Furthermore, although the present invention is illustrated and described herein with references to specific embodiments, the present invention is not intended to be limited to the details shown. Rather, various modifications may be made in the details within the scope and range of equivalents of the claims and without departing from the present invention.

What is claimed:

1. A photovoltaic device comprising:
a photovoltaic layer having a front and a back surface;
a distributed Bragg reflector (DBR) layer having one to three periods disposed adjacent the back surface of the photovoltaic layer;
a metal layer disposed underlying the DBR layer and adapted to reflect light passed through the photovoltaic layer to the DBR layer; and
a phase matching layer disposed between the metal layer and the DBR layer, the phase matching layer configured to match a phase between the DBR layer and the metal layer over a selected wavelength band of incident light.

2. The photovoltaic device according to claim 1, wherein:
the DBR layer is configured to receive the light passed through the photovoltaic layer, reflect a first portion of the passed light to the photovoltaic layer, and pass a second portion of the passed light to the phase matching layer and the metal layer,
the metal layer is configured to reflect the second portion of the passed light through the DBR layer back to the photovoltaic layer.

3. The photovoltaic device of claim 1, further comprising an antireflective (ARC) layer disposed on the front surface of the photovoltaic layer.

4. The photovoltaic device of claim 3, wherein the ARC layer includes a layer of SiO₂ and a layer of Si₃N₄.

5. The photovoltaic device of claim 1, further comprising a substrate on which the metal layer is disposed.

6. The photovoltaic device of claim 5, wherein the substrate is glass.

7. The photovoltaic device of claim 5, wherein the substrate is crystalline silicon.

8. The photovoltaic device of claim 1, wherein the photovoltaic layer comprises amorphous silicon.

9. The photovoltaic device of claim 8, wherein the thickness of the photovoltaic layer is in a range of 100 nm to 2 μm.

10. The photovoltaic device of claim 8, wherein the thickness of the photovoltaic layer is about 500 nm.

11. The photovoltaic device of claim 1, wherein the metal layer comprises aluminum.

12. The photovoltaic device of claim 1, wherein each DBR period includes a layer of SiO₂ and a layer of amorphous silicon.

13. The photovoltaic device of claim 12, wherein the DBR layer includes only one period

14. The photovoltaic device of claim 12 wherein the DBR layer includes a layer of SiO₂ and a layer of amorphous silicon.

15. The photovoltaic device of claim 1, wherein the phase matching layer is a layer of SiO₂.

16. The photovoltaic device of claim 1, wherein the surface of the metal layer facing the phase matching layer comprises a multiplicity of raised areas, the raised areas having width and height dimensions in the range of 0.2 to 1 micron.

17. The photovoltaic device of claim 13, wherein the multiplicity of raised areas is produced by vapor deposition of the metal layer on a substrate.

18. The photovoltaic device of claim 16, wherein the multiplicity of raised areas is produced by vapor deposition of the metal layer on a substrate the substrate also including a multiplicity of raised areas, the raised areas of the substrate generally having a shape from the group consisting of random pyramidal/conical structures, a diffraction grating and regularly shaped pyramidal/conical structures.

19. The photovoltaic device of claim 18, wherein the surface of the substrate comprises a randomly dispersed multiplicity of raised area generally of pyramidal and conical shapes, produced by etching a vapor deposited layer of crystalline silicon.

20. The photovoltaic device of claim 19, where the DBR layer comprises a single period DRB and the photovoltaic layer is amorphous silicon about 500 nanometers thick.
